(19) United States
(12) Patent Application Publication
(10) Pub. No.: US 2025/0201610 A1
(43) Pub. Date: Jun. 19, 2025

(54) RETICLE CARRIER AND METHOD FOR MANUFACTURING AUXILIARY STRUCTURE IN RETICLE CARRIER

(71) Applicant: TAIWAN SEMICONDUCTOR MANUFACTURING COMPANY, LTD., Hsinchu (TW)

(72) Inventors: Lu-Chih LIN, Hsinchu County (TW); Pei-Cheng HSU, Taipei City (TW); Ta-Cheng LIEN, Hsinchu County (TW); Tran-Hui SHEN, Yunlin County (TW); Tzu-Yi WANG, Hsinchu City (TW); Hsin-Chang LEE, Hsinchu County (TW)

(73) Assignee: TAIWAN SEMICONDUCTOR MANUFACTURING COMPANY, LTD., Hsinchu (TW)

(21) Appl. No.: 18/405,695

(22) Filed: Jan. 5, 2024

Related U.S. Application Data
(60) Provisional application No. 63/611,202, filed on Dec. 17, 2023.

(51) Int. Cl. H01L 21/673; C23C 16/04; C23C 16/26; G03F 7/16

(52) U.S. Cl. CPC H01L 21/67383; C23C 16/042; C23C 16/26; G03F 7/16; H01L 21/67359

(57) ABSTRACT

A reticle carrier includes an inner pod, a first auxiliary structure, and an outer pod. The inner pod is configured to receive a reticle. The inner pod comprises an inner baseplate and an inner cover plate, and an inner surface of the inner baseplate and an inner surface of the inner cover plate face each other. The first auxiliary structure is on one of the inner surface of the inner baseplate and the inner surface of the inner cover plate. The first auxiliary structure includes a raised structure and a contact pattern on the raised structure, and the contact pattern includes a plurality of parallel strips. The outer pod houses the inner pod.

### PRIORITY CLAIM AND CROSS-REFERENCE

This application claims priority to U.S. Provisional Application Ser. No. 63/611,202, filed Dec. 17, 2023, which is herein incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC processing and manufacturing are needed.

Semiconductor lithography processes may use lithographic templates (e.g., photomasks or reticles) to optically transfer patterns onto a substrate. Such a process may be accomplished, for example, by projection of a radiation source, through an intervening photomask or reticle, onto the substrate having a photosensitive material (e.g., photoresist) coating. The minimum feature size that may be patterned by way of such a lithography process is limited by the wavelength of the projected radiation source. In view of this, extreme ultraviolet (EUV) radiation sources and lithographic processes have been introduced. However, EUV processes are very sensitive to contamination issues. Particle contamination introduced onto an EUV reticle can result in significant degradation of the lithographically transferred pattern. A EUV reticle pod carries the EUV reticle for transportation, and the particle contamination may occur during the transportation. Thus, existing EUV reticle pods have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic view of a carrier accommodating a reticle in accordance with some embodiments of the present disclosure.

FIG. 1B is a cross-sectional view of an inner pod of FIG. 1A.

FIG. 2A is a schematic view of an auxiliary structure of a carrier accommodating a reticle in accordance with some embodiments of the present disclosure.

FIG. 2B is a schematic top view of a contact region of the auxiliary structure of FIG. 2A.

FIG. 2C is a schematic cross-sectional view of the contact region of the auxiliary structure taken along a line X-X of FIG. 2B.

FIG. 3A is a schematic top view showing a reticle held by auxiliary structures in accordance with some embodiments of the present disclosure.

FIG. 3B is a schematic cross-sectional view showing a contact region of an auxiliary structure holding a reticle in movement in accordance with some embodiments of the present disclosure.

FIG. 4A is a schematic top view of a contact region of an auxiliary structure in accordance with some embodiments of the present disclosure.

FIG. 4B is a schematic cross-sectional view of the contact region of the auxiliary structure taken along a line X-X of FIG. 4A.

FIG. 5A is a schematic top view of a contact region of an auxiliary structure in accordance with some embodiments of the present disclosure.

FIG. 5B is a schematic cross-sectional view of the contact region of the auxiliary structure taken along a line X-X of FIG. 5A.

FIG. 6A is a schematic top view of a contact region of an auxiliary structure in accordance with some embodiments of the present disclosure.

FIG. 6B is a schematic cross-sectional view of the contact region of the auxiliary structure taken along a line X-X of FIG. 6A.

FIG. 7A is a schematic top view of a contact region of an auxiliary structure in accordance with some embodiments of the present disclosure.

FIG. 7B is a schematic cross-sectional view of the contact region of the auxiliary structure taken along a line X-X of FIG. 7A.

FIG. 8 is a schematic view of an inner pod accommodating a reticle in accordance with some embodiments of the present disclosure.

FIG. 9 is a schematic view of an inner pod accommodating a reticle in accordance with some embodiments of the present disclosure.

FIG. 10 is a top view showing a configuration of auxiliary structures on a main plate in accordance with some embodiments of the present disclosure.

FIG. 11 is a top view showing a configuration of auxiliary structures on a main plate in accordance with some embodiments of the present disclosure.

FIG. 12 is a top view showing a configuration of auxiliary structures on a main plate in accordance with some embodiments of the present disclosure.

FIG. 13 is a top view showing a configuration of auxiliary structures on a main plate in accordance with some embodiments of the present disclosure.

FIG. 14A is a top view of a reticle supporting by contact regions in accordance with some embodiments of the present disclosure.

FIG. 14B is a cross-sectional view of a reticle fabricated using a negative chemically-amplified resist taken along line M-M of FIG. 14A.

FIG. 14C is a cross-sectional view of a reticle fabricated using a positive chemically-amplified resist taken along line M-M of FIG. 14A.

FIGS. 15-20B illustrate a method of manufacturing a contact region of an auxiliary structure at various stages in accordance with some embodiments of the present disclosure.

FIGS. 21-25 are top views illustrating a method of manufacturing a contact region of an auxiliary structure at various stages in accordance with some embodiments of the present disclosure.

FIGS. 26-30 are top views illustrating a method of manufacturing a contact region of an auxiliary structure at various stages in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

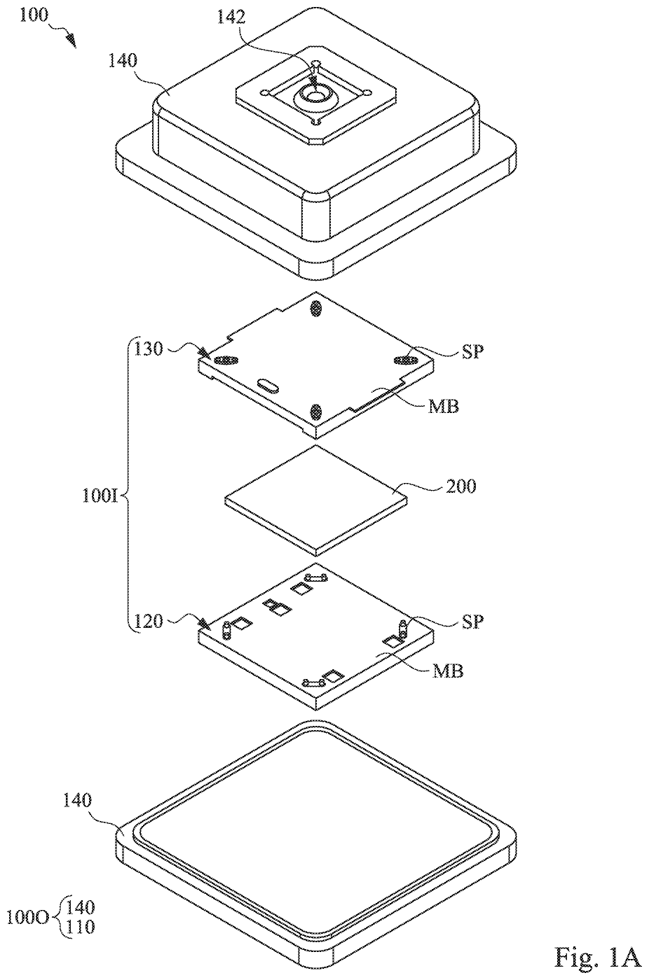

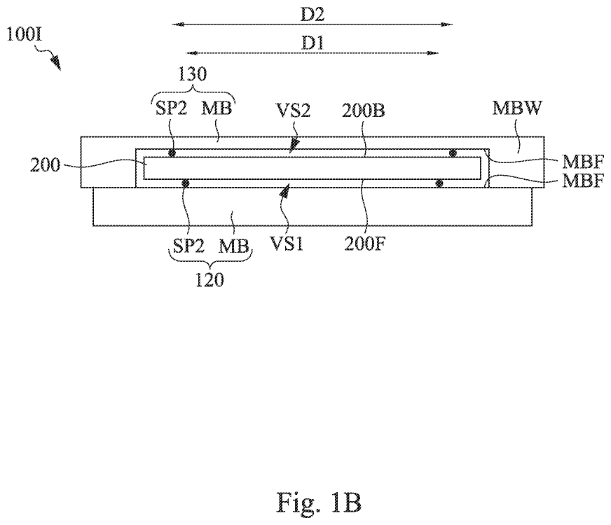

FIG. 1A is a schematic view of a carrier 100 accommodating a reticle 200 in accordance with some embodiments of the present disclosure. The carrier 100 may be a dual pod carrier including an outer pod 100O and an inner pod 100I. The outer pod 100O includes an outer baseplate 110 and an outer cover plate 140. The outer baseplate 110 may serve as a carrier door. The outer cover plate 140 may include a lift plate 142 compatible with an overhead hoist transport (OHT) system to be lifted up by an OHT vehicle. The inner pod 100I includes an inner baseplate 120 and an inner cover plate 130. The reticle 200 is housed within the inner pod 100I between the inner baseplate 120 and the inner cover plate 130. In some embodiments, the reticle 200 may be an extreme ultraviolet (EUV) lithography reticle.

FIG. 1B is a cross-sectional view of an inner pod 100I of FIG. 1A. Reference is made to FIG. 1A and FIG. 1B. In some embodiments, each of the inner baseplate 120 and the inner cover plate 130 has a main plate MB and auxiliary structures SP. In some embodiments, the main plates MB include a conductive material (e.g., Al—Mg alloy), which may be used to apply a voltage potential. In some embodiments, the main plates MB may be coated with a hard protection layer (e.g., Ni, NiP, or Cr) for mechanically protecting the light-weight conductive material (e.g., Al—Mg alloy). Each of the main plates MB may has a substantially flat surface MBF facing each other. The auxiliary structures SP are disposed on the substantially flat surface MBF of the main plates MB. The auxiliary structures SP may create a vertical separation (i.e., a vertical spacing) between the inner baseplate 120 and the inner cover plate 130. The auxiliary structures SP of the inner baseplate 120 may be referred to as supporting auxiliary structures SP, while the auxiliary structures SP of the inner baseplate 120 may be referred to as hold-down auxiliary structures SP. In some embodiments, the reticle 200 is oriented face-down within the inner pod 100I. With the reticle 200 in place, the supporting auxiliary structures SP may create a vertical separation (i.e., a vertical spacing or gap) VS1 between the inner baseplate 120 and a front surface 200F of the reticle 200, and the hold-down auxiliary structures SP may create a vertical separation (i.e., a vertical spacing or gap) VS2 between the inner cover plate 130 and a back surface 200B of the reticle 200.

Each of the auxiliary structure SP is depicted as a dot, indicating a contact region SP2 of the auxiliary structure SP contacting the reticle 200 in FIG. 1B. In some embodiments, the contact region SP2 of the auxiliary structure SP of the inner cover plate 130 is misaligned with the contact region SP2 of the auxiliary structure SP of the inner baseplate 120. For example, as shown in FIG. 1B, a distance D1 between the contact regions SP2 of the auxiliary structures SP of the inner baseplate 120 is less than a distance D2 between the contact regions SP2 of the auxiliary structures SP of the inner cover plate 130. Stated differently, the contact region SP2 of the auxiliary structure SP of the inner cover plate 130 is closer to an edge of the reticle 200 than the contact region SP2 of the auxiliary structure SP of the inner baseplate 120 is. This configuration may provide well mechanical support to the reticle 200. In some other embodiments, the contact region SP2 of the auxiliary structure SP of the inner cover plate 130 may be aligned with the contact region SP2 of the auxiliary structure SP of the inner baseplate 120.

In the present embodiments, the main plate MB of the inner cover plate 130 may include an edge wall MBW meeting with the main plate MB of the inner baseplate 120, which may provide well seal effect between the inner cover plate 130 and the inner baseplate 120, thereby prevent particle flow to reticle surface during load-port vending.

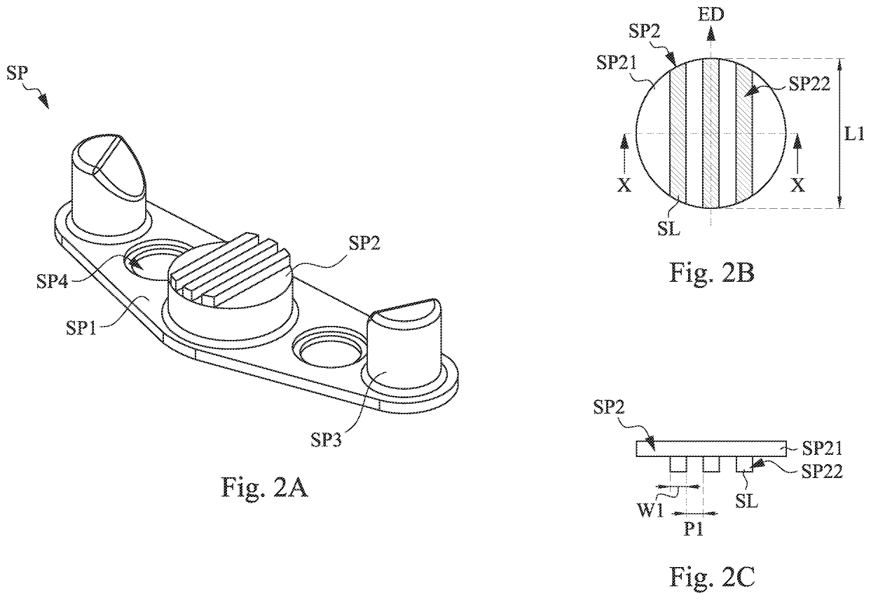

FIG. 2A is a schematic view of an auxiliary structure SP of the carrier 100 accommodating a reticle 200 (referring to FIGS. 1A and 1B) in accordance with some embodiments of the present disclosure. The auxiliary structure SP may include a baseplate SP1, a contact region SP2, a pair of reticle-positioning posts SP3, and fixing elements SP4. The contact region SP2 may protrude from the baseplate SP1. With the reticle 200 (referring to FIGS. 1A and 1B) in place, the contact region SP2 is configured to touch the front surface 200F or the back surface 200B of the reticle 200 (referring to FIGS. 1A and 1B), thereby vertically fixing the reticle 200 in the carrier 100 (referring to FIGS. 1A and 1B) and spacing the front surface 200F or the back surface 200B of the reticle 200 (referring to FIGS. 1A and 1B) from the baseplate SP1. The pair of the reticle-positioning post SP3 may have a height greater than a height of the contact region SP2. The pair of the reticle-positioning post SP3 may be configured to contact two adjacent sides of the reticle 200 (referring to FIGS. 1A and 1B), thereby holding a corner of the reticle 200 defined by the two adjacent sides of the reticle 200. The fixing elements SP4 may include holes allowing screws extending through, thereby screw-fixing the auxiliary structure SP to the main plate MB.

FIG. 2B is a schematic top view of the contact region SP2 of the auxiliary structure SP of FIG. 2A. FIG. 2C is a schematic cross-sectional view of the contact region SP2 of the auxiliary structure SP taken along a line X-X of FIG. 2B. The contact region SP2 may include a raised structure SP21 standing over the baseplate SP1 (referring to FIG. 2A) and a contact pattern SP22 on the raised structure SP21. The raised structure SP21 may also be referred to as a plateau structure or a mesa structure in some embodiments. The contact pattern SP22 may also be referred to as support pins or hold-down pins in some embodiments. In the present embodiments, the contact pattern SP22 may include plural strips SL. The strips SL of the contact pattern SP22 may have substantially flat surfaces facing away from the raised structure SP21, and the flat surfaces of strips SL of the contact pattern SP22 are substantially coplanar for supporting/holding the reticle 200 (referring to FIGS. 1A and 1B). In FIG. 2B, the strips SL may be parallel and extends substantially along an extension direction ED in the present embodiments. For example, the contact pattern SP22 may include vertical straight parallel strips SL extending substantially along a vertical extension direction ED. The straight strips SL of the contact pattern SP22 may extend from a side (e.g., a top side) of the raised structure SP21 to another side (e.g., a bottom side) of the raised structure SP21. In some other examples, the contact pattern SP22 may include other shapes, such as angle parallel strips, curved parallel strips, zigzag parallel strips, the like, or the combination thereof.

In some embodiments, the contact region SP2 may have a length (or diameter) L1 in a range from about 1 millimeter to about 5 millimeters. If the length L1 is greater than about 5 millimeters, the contact area may increase, which may consume the contact region SP2 and enlarge a contaminated area. If the length L1 is less than about 1 millimeter, a pressure between the auxiliary structure and the reticle may become too large, which may result in severe damage to the reticle surface. In some embodiments, the strips SL of the contact pattern SP22 may have a width W1 in a range from about 0.1 millimeter to about 1.7 millimeters. If the width W1 is greater than about 1.7 millimeters, the contact area may increase, which may consume the contact region SP2 and enlarge a contaminated area. If the width W1 is less than about 0.1 millimeter, the small contact area would increase a pressure between the auxiliary structure and the reticle, which may result in severe damage to the reticle surface. In some embodiments, every two adjacent strips SL of the contact pattern SP22 have a space P1 therebetween, and the space P1 may be in a range from about 0.1 millimeter to about 1.7 millimeters. If the space P1 is greater than about 1.7 millimeters, the small contact area would increase a pressure between the auxiliary structure and the reticle, which may result in severe damage to reticle surface. If the space P1 is less than about 0.1 millimeter, the contact area may increase, which may consume the contact region SP2 and enlarge a contaminated area. A ratio of the width W1 and space P1 may be in a range from about 0.5 to about 1.5. If the ratio of the width W1 and space P1 is greater than about 1.5, the contact area may increase, which may consume the contact region SP2 and enlarge a contaminated area. If the ratio of the width W1 and space P1 is less than about 0.5 millimeter, the small contact area would increase a pressure between the auxiliary structure and the reticle, which may result in severe damage to the reticle surface. The contact pattern SP22 of the contact region SP2 may include 3 to 6 strips SL. If the number of the strips SL of the contact pattern SP22 is greater than 6, the small contact area would increase a pressure between the auxiliary structure and the reticle, which may result in severe damage to the reticle surface. If the number of the strips SL of the contact pattern SP22 is less than 3, the contact area may increase, which may consume the contact region SP2 and enlarge a contaminated area.

In some embodiments, the auxiliary structure SP (including the baseplate SP1, the raised structure SP21, the contact pattern SP22) may be integrally fabricated and include a same dielectric material. For example, the auxiliary structure SP (including the baseplate SP1, the raised structure SP21, the contact pattern SP22) may include a same dielectric material, such as standard thermoplastic, engineering thermoplastic, high-performance thermoplastic, fiber-reinforced high-performance thermoplastic, ultra high molecular weight polyethylene (UHMWPE), the like, or the combination thereof. The standard thermoplastic may include low-density polyethylene (PE-LD), linear low-density polyethylene (PE-LLD), high-density polyethylene (PE-HD), polypropylene (PP), polystyrene (PS), polyvinyl chloride (PVC), high impact polystyrene (PS-HI), acrylonitrile butadiene styrene (ABS), or the like. The engineering thermoplastic may include polyoxymethylene (POM), polymethyl methacrylate (PMMA), polyamide 6 (PA6), polyamide 46 (PA46), polyamide 66 (PA66), styrene acrylonitrile (SAN), polybutylene terephthalate (PBT), polyethylene terephthalate (PET), polycarbonates (PC), a mixture of PC/PET, a mixture of PC/ABS, thermoplastic elastomers (TPE), syndiotactic polystyrene (sPS), polyphthalamide (PPA), polyamide 11/12 (PA11/12). The high-performance thermoplastic may include polyether ether ketone (PEEK), polyetherketone (PEK), polyamide-imide (PAI), polyphenylsulfone (PPSU)), polyphenylene sulfide (PPS), polysulfone (PSU), polyethersulfone (PES), or the like. The material of the baseplate SP1, the raised structure SP21, the contact pattern SP22 may be semi-crystalline or amorphous depending on requirements. The fiber-reinforced high-performance thermoplastic may be a mixture of carbon nanotubes (CNTs) and a high-performance thermoplastic (e.g., PEEK). When the contact pattern SP22 include the mixture of CNTs and PEEK, the CNTs may have a suitable weight ratio in the mixture. For example, the weight ratio of the CNTs in the mixture may be in a range from about 15% to about 45%.

In some embodiments, the contact pattern SP22 may be fabricated using a dielectric material different from that of the baseplate SP1 and the raised structure SP21. The contact pattern SP22 may be more flexible than the baseplate SP1 and the raised structure SP21 are. Stated differently, a stiffness of the contact pattern SP22 may be less than a stiffness of the baseplate SP1 and the raised structure SP21, in which stiffness is the extent to which an object resists deformation in response to an applied force. For example, in some embodiments, the contact pattern SP22 may be fabricated using a high-performance thermoplastic, UHMWPE, or a fiber-reinforced high-performance thermoplastic, and the baseplate SP1 and the raised structure SP21 may be fabricated using other materials (e.g., other high-performance thermoplastic without being fiber-reinforced, standard thermoplastic or engineering thermoplastic).

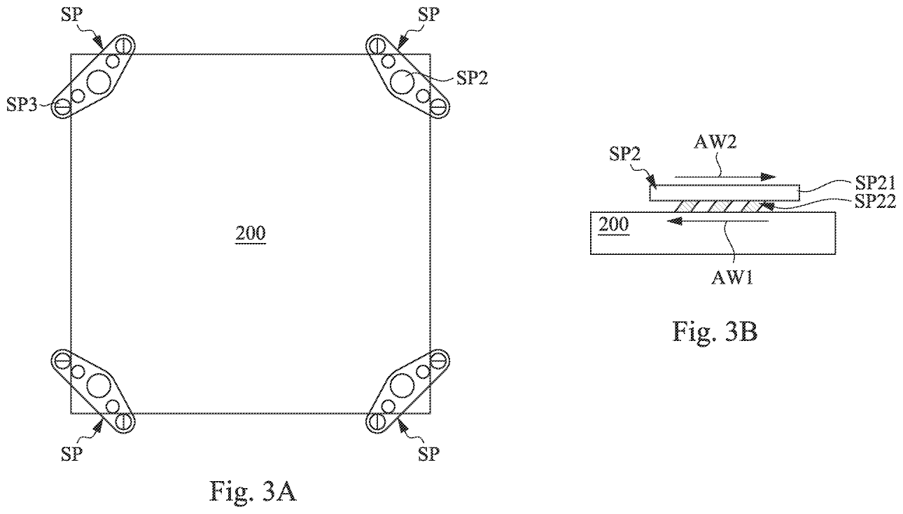

FIG. 3A is a schematic top view showing a reticle 200 held by the auxiliary structures SP in accordance with some embodiments of the present disclosure. As shown in FIG. 3A, four corners of the reticle 200 are respectively held by the four auxiliary structures SP. For example, each of the corners of the reticle 200 is in contact with the contact region SP2 of one of the auxiliary structures SP. The contact regions SP2 provide vertical support and vertical pressure to the reticle 200, thereby vertically fixing the reticle 200 in the carrier 100 (referring to FIG. 1A). Also, each of the corners of the reticle 200 has two adjacent sides respectively in contact with two reticle-positioning posts SP3 of one of the auxiliary structures SP. The reticle-positioning posts SP3 laterally limit the position of the reticle 200, thereby horizontally fixing the reticle 200 in the carrier 100 (referring to FIG. 1A).

FIG. 3B is a schematic cross-sectional view showing a contact region SP2 of an auxiliary structure SP holding a reticle 200 in movement in accordance with some embodiments of the present disclosure. During transportation, when the carrier 100 (referring to FIG. 1A) is accelerated from left to right, the reticle 200 is moved leftward. The movement of reticle 200 may cause force at a top and a bottom the contact pattern SP22 as indicated by an arrow AW1 and the arrow AW2. The contact pattern SP22 with parallel strips SL has a flatter and suitable contact area, in which the suitable contact area large enough to a low pressure for avoiding the imprint and scratch caused by the contact pattern SP22, and the suitable contact area is also small enough to avoid a friction consumption of the contact pattern SP22.

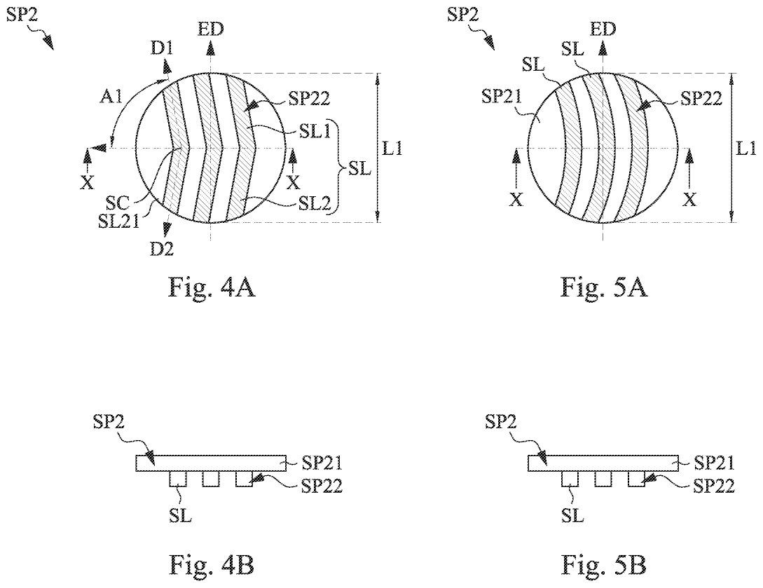

FIG. 4A is a schematic top view of a contact region of an auxiliary structure in accordance with some embodiments of the present disclosure. FIG. 4B is a schematic cross-sectional view of the contact region of the auxiliary structure taken along a line X-X of FIG. 4A. Details of the present embodiments are similar to the embodiments of FIGS. 2A-2C, except that the contact pattern SP22 includes angle parallel strips SL in the present embodiments. The angle parallel strips SL of the contact pattern SP22 may extend from a side (e.g., a top side) of the raised structure SP21 to another side (e.g., a bottom side) of the raised structure SP21. This contact pattern SP22 including the angle parallel strips SL can share more force from different directions. For example, each of the angle parallel strips SL may include a first parallel strip portion SL1 and a second parallel strip portion SL2 meeting with the first parallel strip portion SL1 at a point SC, the first parallel strip portion SL1 extends from the point SC substantially along a direction D1, and the second parallel strip portion SL2 extends from the point SC substantially along a direction D2 different from the direction D1. The angle parallel strips SL may have an angle direction AD, which may be an average or mean vector of the directions D1 and D2. An angle A1 between the direction D1/D2 and the angle direction AD is in a range from about 30 degrees to about 50 degrees. If the angle A1 is greater than about 50 degrees or less than about 30 degrees, the contact pattern SP22 may not share force from different directions. In some embodiments, the angle parallel strips SL may also have an extension direction ED perpendicular to the angle direction AD. Other details are similar to those illustrated above, and thereto not repeated herein.

FIG. 5A is a schematic top view of a contact region of an auxiliary structure in accordance with some embodiments of the present disclosure. FIG. 5B is a schematic cross-sectional view of the contact region of the auxiliary structure taken along a line X-X of FIG. 5A. Details of the present embodiments are similar to the embodiments of FIGS. 2A-2C, except that the contact pattern SP22 includes curved parallel strips SL in the present embodiments. The curved parallel strips SL of the contact pattern SP22 may extend from a side (e.g., a top side) of the raised structure SP21 to another side (e.g., a bottom side) of the raised structure SP21. This contact pattern SP22 including the curved parallel strips SL can share force in several directions. Other details are similar to those illustrated above, and thereto not repeated herein.

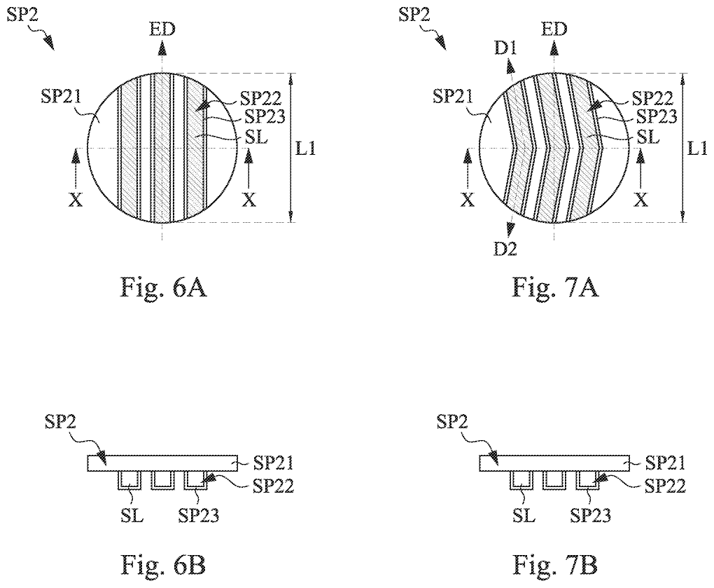

FIG. 6A is a schematic top view of a contact region SP2 of an auxiliary structure in accordance with some embodiments of the present disclosure. FIG. 6B is a schematic cross-sectional view of the contact region SP2 of the auxiliary structure taken along a line X-X of FIG. 6A. Details of the present embodiments are similar to the embodiments of FIGS. 2A-2C, except that the contact region SP2 further includes a contact layer SP23 over the strips SL of the contact pattern SP22. In some embodiments, a stiffness of the contact layer SP23 may be less than a stiffness of the contact pattern SP22 or a stiffness of the baseplate SP21. The contact layer SP23 may one or more suitable flexible materials, such as silicones, polymerized siloxanes, polystyrene ethylene-butylene-styrene, thermoplastic elastomer (TPE), the like, or the combination thereof. The flexible material can avoid two hard material (e.g., between the reticle and the contact pattern) of inner pod friction during pod transferring.

In the present embodiments, the contact layer SP23 includes straight parallel strips extending along a same direction as the straight parallel strips SL of the contact pattern SP22 does. The straight parallel strips of the contact layer SP23 may be spaced apart from each other in the present embodiments. In some embodiments, the contact layer SP23 may be a continuous film covering the contact pattern SP22. Other details are similar to those illustrated above, and thereto not repeated herein.

FIG. 7A is a schematic top view of a contact region of an auxiliary structure in accordance with some embodiments of the present disclosure. FIG. 7B is a schematic cross-sectional view of the contact region of the auxiliary structure taken along a line X-X of FIG. 7A. Details of the present embodiments are similar to the embodiments of FIGS. 4A and 4B, except that the contact region SP2 further include a contact layer SP23 over the contact pattern SP22. The contact layer SP23 may include parallel strips of the same shape as the contact pattern SP22 does. In the present embodiments, the contact layer SP23 includes angle parallel strips as the angle parallel strips SL of the contact pattern SP22. For example, the angle parallel strips of the contact layer SP23 may include first parallel strip portions extending substantially along a direction D1 and second parallel strip portions extending substantially along a direction D2 different from the direction D1. In the present embodiments, the parallel strips of the contact layer SP23 are spaced apart from each other. In some other embodiments, the contact layer SP23 may be a continuous film covering the contact pattern SP22. Other details are similar to those illustrated above, and thereto not repeated herein.

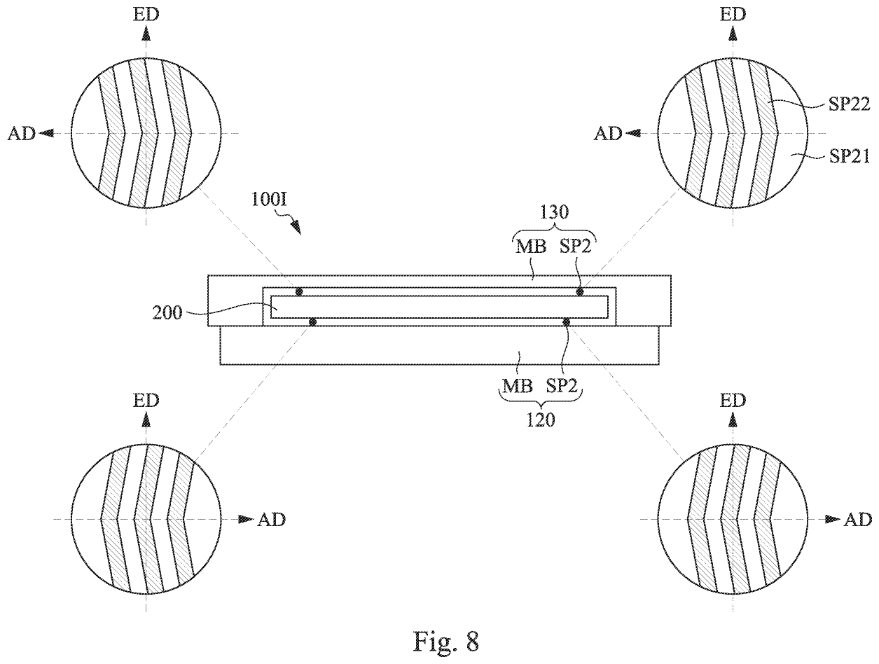

FIG. 8 is a schematic view of an inner pod 100I accommodating a reticle 200 in accordance with some embodiments of the present disclosure. Insets in FIG. 8 are top views of the contact regions SP2 of the auxiliary structures SP of the inner baseplate 120 and the inner cover plate 130. In the present embodiment, top views of the contact patterns SP22 of the contact region SP2 of the inner baseplate 120 may be different from top views of the contact patterns SP22 of the contact region SP2 of the inner cover plate 130. The contact patterns SP22 of the contact region SP2 of the inner baseplate 120 may include different strip shape, strip width, strip space (pitch), strip orientation, the like, or the combination thereof, from the contact patterns SP22 of the contact region SP2 of the inner cover plate 130. For example, the contact patterns SP22 of the contact region SP2 of the inner baseplate 120 and the inner cover plate 130 may both include angle parallel strips, but an orientation of the angle parallel strips of the contact patterns SP22 of the inner baseplate 120 is different from an orientation of the angle parallel strips of the contact patterns SP22 of the inner cover plate 130. In the present embodiments, the angle direction AD of the contact patterns SP22 of the inner baseplate 120 is opposite to the angle direction AD of the contact patterns SP22 of the inner cover plate 130. For example, the angle direction AD of the contact patterns SP22 of the inner baseplate 120 is oriented rightward, and the angle direction AD of the contact patterns SP22 of the inner cover plate 130 is oriented leftward.

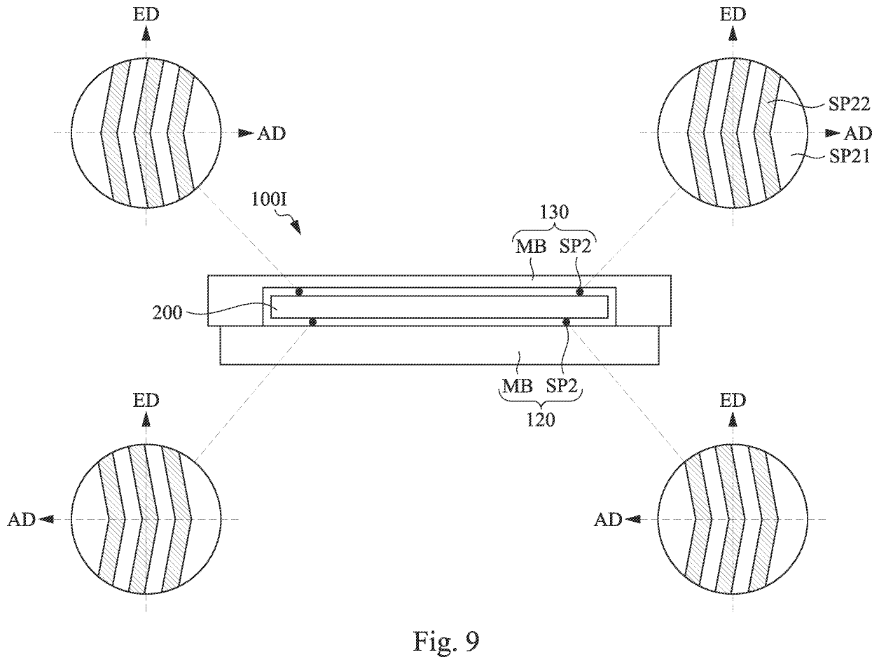

FIG. 9 is a schematic view of an inner pod 100I accommodating a reticle 200 in accordance with some embodiments of the present disclosure. Insets in FIG. 9 are top views of the contact regions SP2 of the auxiliary structures SP of the inner baseplate 120 and the inner cover plate 130. Details of the present embodiments are similar to those illustrated in FIG. 8, except that the angle direction AD of the contact patterns SP22 of the inner baseplate 120 is oriented leftward, and the angle direction AD of the contact patterns SP22 of the inner cover plate 130 is oriented rightward. Other details of the present embodiments are similar to those illustrated in FIG. 8, and thereto not repeated herein.

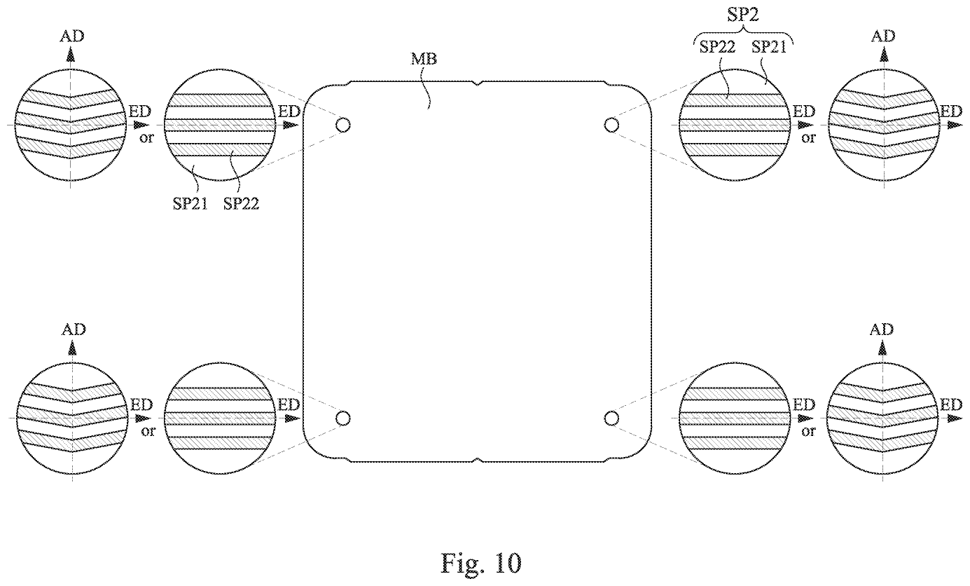

FIG. 10 is a top view showing a configuration of contact regions SP2 on a main plate MB in accordance with some embodiments of the present disclosure. Insets in FIG. 10 are top views of the contact regions SP2. One or more of the contact patterns SP22 of the contact region SP2 on a same main plate MB may include different strip shape, strip width, strip space (pitch), strip orientation, the like, or the combination thereof, from each other. As illustrated in FIG. 10, each of the four contact regions SP2 may include a contact pattern SP22 of angle parallel strips or a contact pattern SP22 of horizontal parallel strips. In present embodiments, the extension direction ED of the angle parallel strips may be substantially parallel with the extension direction ED of the horizontal parallel strips. In some other embodiments, the extension direction ED of the angle parallel strips may not be parallel with the extension direction ED of the horizontal parallel strips. The angle direction AD of the angle parallel strips may be oriented upward in the present embodiments. In some other embodiments, the angle direction AD of the angle parallel strips may be oriented in other suitable directions, such as downward or the like.

In first embodiments, all the four contact regions SP2 include a contact pattern SP22 of angle parallel strips. In second embodiments, three of the four contact regions SP2 include a contact pattern SP22 of angle parallel strips, and one of the four contact regions SP2 includes a contact pattern SP22 of horizontal parallel strips. In third embodiments, two of the four contact regions SP2 include a contact pattern SP22 of angle parallel strips, and two of the contact regions SP2 include a contact pattern SP22 of horizontal parallel strips. In fourth embodiments, one of the four contact regions SP2 includes a contact pattern SP22 of angle parallel strips, and three of the four contact regions SP2 include a contact pattern SP22 of horizontal parallel strips. In fifth embodiments, all the four contact regions SP2 include a contact pattern SP22 of horizontal parallel strips.

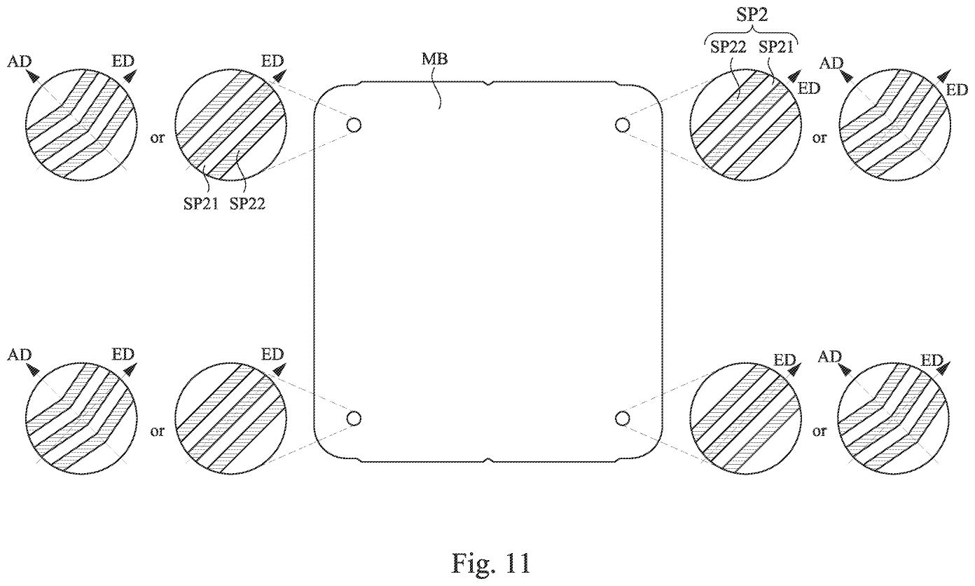

FIG. 11 is a top view showing a configuration of contact regions SP2 on a main plate MB in accordance with some embodiments of the present disclosure. Insets in FIG. 11 are top views of the contact regions SP2. As illustrated in FIG. 11, each of the four contact regions SP2 may include a contact pattern SP22 of angle parallel strips or a contact pattern SP22 of oblique parallel strips. In present embodiments, the extension direction ED of the angle parallel strips may be substantially parallel with the extension direction ED of the oblique parallel strips. In some other embodiments, the extension direction ED of the angle parallel strips may not be parallel with the extension direction ED of the oblique parallel strips. The angle direction AD of the angle parallel strips may be oriented in diagonal up left direction in the present embodiments. In some other embodiments, the angle direction AD of the angle parallel strips may be oriented in other suitable directions, such as a diagonal down right direction.

In first embodiments, all the four contact regions SP2 include a contact pattern SP22 of angle parallel strips. In second embodiments, three of the four contact regions SP2 include a contact pattern SP22 of angle parallel strips, and one of the four contact regions SP2 includes a contact pattern SP22 of oblique parallel strips. In third embodiments, two of the four contact regions SP2 include a contact pattern SP22 of angle parallel strips, and two of the four contact regions SP2 include a contact pattern SP22 of oblique parallel strips. In fourth embodiments, one of the four contact regions SP2 includes a contact pattern SP22 of angle parallel strips, and three of the contact regions SP2 include a contact pattern SP22 of oblique parallel strips. In fifth embodiments, all the four contact regions SP2 include a contact pattern SP22 of oblique parallel strips.

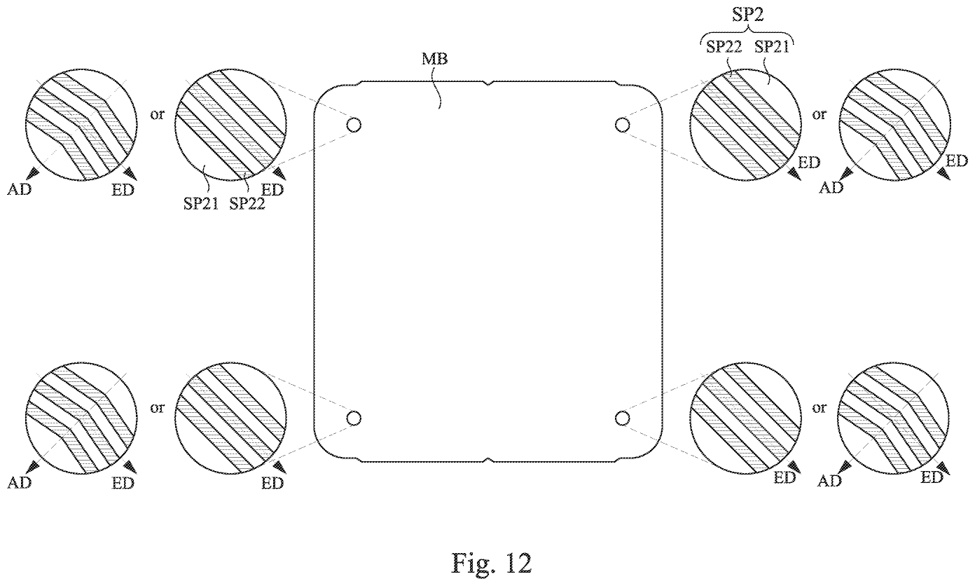

FIG. 12 is a top view showing a configuration of contact regions SP2 on a main plate MB in accordance with some embodiments of the present disclosure. Insets in FIG. 12 are top views of the contact region SP2. As illustrated in FIG. 12, each of the four contact regions SP2 may include a contact pattern SP22 of angle parallel strips or a contact pattern SP22 of oblique parallel strips. In the present embodiments, the extension direction ED of the angle parallel strips may not be parallel with the extension direction ED of the oblique parallel strips. In some other embodiments, the extension direction ED of the angle parallel strips may be substantially parallel with the extension direction ED of the oblique parallel strips. The angle direction AD of the angle parallel strips may be oriented in diagonal down left direction in the present embodiments. In some other embodiments, the angle direction AD of the angle parallel strips may be oriented in other suitable directions, such as a diagonal up right direction.

In first embodiments, all the four contact regions SP2 include a contact pattern SP22 of angle parallel strips. In second embodiments, three of the four contact regions SP2 include a contact pattern SP22 of angle parallel strips, and one of the four contact regions SP2 includes a contact pattern SP22 of oblique parallel strips. In third embodiments, two of the four contact regions SP2 include a contact pattern SP22 of angle parallel strips, and two of the four contact regions SP2 include a contact pattern SP22 of oblique parallel strips. In fourth embodiments, one of the four contact regions SP2 includes a contact pattern SP22 of angle parallel strips, and three of the four contact regions SP2 include a contact pattern SP22 of oblique parallel strips. In fifth embodiments, all the four contact regions SP2 include a contact pattern SP22 of oblique parallel strips.

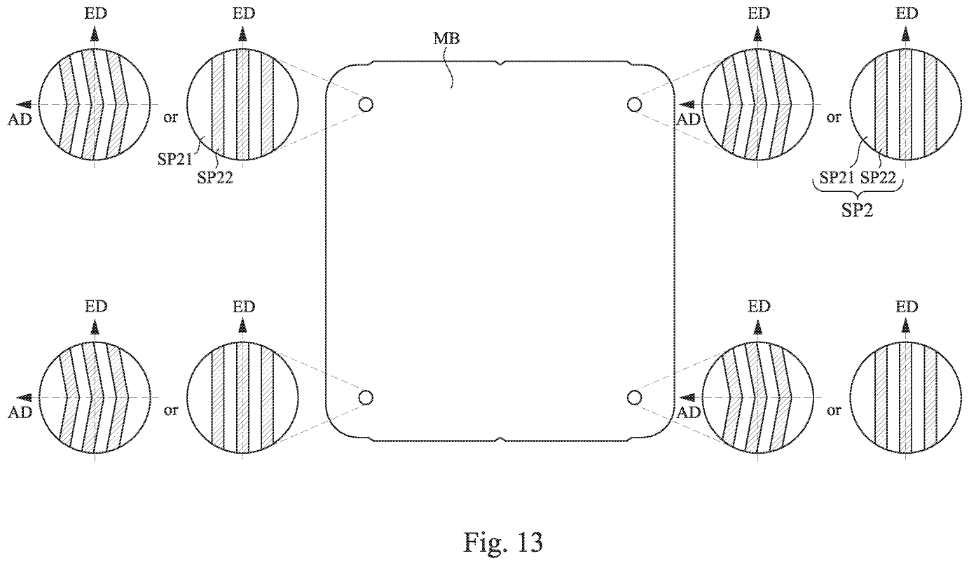

FIG. 13 is a top view showing a configuration of contact regions SP2 on a main plate MB in accordance with some embodiments of the present disclosure. Insets in FIG. 13 are top views of the contact region SP2 of the contact regions SP2. As illustrated in FIG. 13, each of the four contact regions SP2 may include a contact pattern SP22 of angle parallel strips or a contact pattern SP22 of vertical parallel strips. In present embodiments, the extension direction ED of the angle parallel strips may be substantially parallel with the extension direction ED of the vertical parallel strips. In some other embodiments, the extension direction ED of the angle parallel strips may not be parallel with the extension direction ED of the vertical parallel strips. The angle direction AD of the angle parallel strips may be oriented leftward in the present embodiments. In some other embodiments, the angle direction AD of the angle parallel strips may be oriented in other suitable directions, such as a horizontal direction.

In first embodiments, all the four contact regions SP2 include a contact pattern SP22 of angle parallel strips. In second embodiments, three of the four contact regions SP2 include a contact pattern SP22 of angle parallel strips, and one of the four contact regions SP2 includes a contact pattern SP22 of vertical parallel strips. In third embodiments, two of the four contact regions SP2 include a contact pattern SP22 of angle parallel strips, and two of the four contact regions SP2 include a contact pattern SP22 of vertical parallel strips. In fourth embodiments, one of the four contact regions SP2 includes a contact pattern SP22 of angle parallel strips, and three of the four contact regions SP2 include a contact pattern SP22 of vertical parallel strips. In fifth embodiments, all the four contact regions SP2 include a contact pattern SP22 of vertical parallel strips.

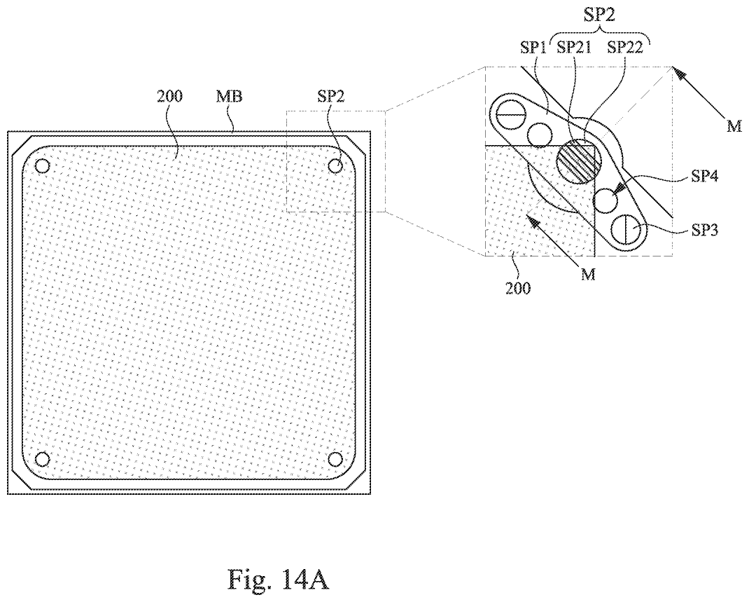

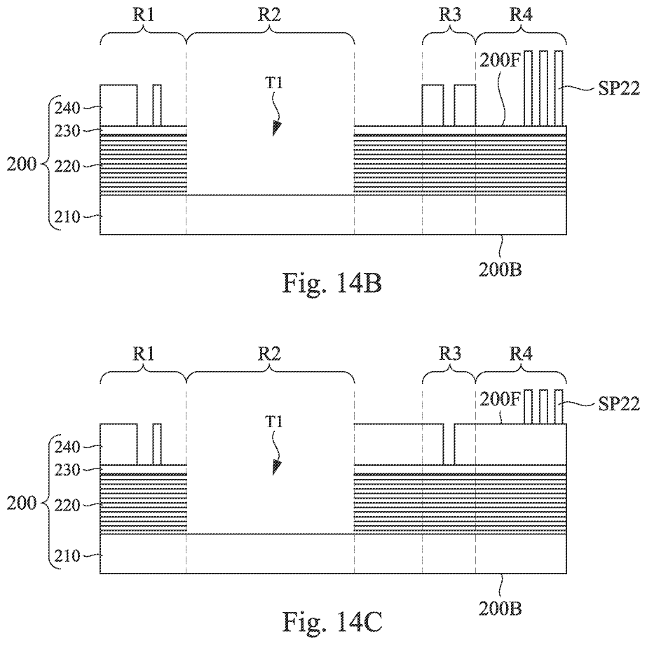

FIG. 14A is a top view of a reticle 200 supporting by contact regions SP2 in accordance with some embodiments of the present disclosure. As illustrated above, the contact regions SP2 are configured to touch the front/back surface of the reticle 200, thereby vertically fixing the reticle 200 in the carrier 100 and spacing the front/back surface of the reticle 200 from the main plate MB. The pair of the reticle-positioning posts SP3 may be configured to contact two adjacent sides of the reticle 200, thereby holding a corner of the reticle 200 defined by the two adjacent sides of the reticle 200.

FIG. 14B is a cross-sectional view of a reticle 200 fabricated using a negative chemically-amplified resist (NCAR) taken along line M-M of FIG. 14A. Reference is made to FIGS. 14A and 14B. In some embodiments, the reticle 200 includes a substrate 210, a multi-layer structure 220, a capping layer 230, and an absorber layer 240. For example, the substrate 210 includes a low thermal expansion material (LTEM) substrate. By way of example, the multi-layer structure 220 may include molybdenum-silicon (Mo—Si) multi-layers deposited on top of the substrate 210 for example, using an ion deposition technique. In various embodiments, the capping layer 230 includes a Ru capping layer. In some other examples, the capping layer 230 may include a Si capping layer. The capping layer 230 may help to protect the multi-layer structure 220 (e.g., during mask manufacturing) and may also serve as an etch-stop layer for a subsequent absorber layer etch process. In some embodiments, the absorber layer 240 may include for example, a TaₓN_{y} layer or a TaₓB_{y}O_{z}Nᵤ layer, and are configured to absorb extreme ultraviolet light. In some examples, other materials may be used for the absorber layer 240, such as Al, Cr, Ta, W, the like, or the combination thereof.

In some embodiments, the reticle 200 includes a main pattern region R1, a black border region R2, a mark region R3, and an outer region R4. The main pattern region R1 may include plural device pattern regions used to define IC features on a wafer and a scribe line region separating surrounding the device pattern regions. The black border region R2 surrounds the main pattern region R1 in a top view. The black border region R2 may serve as a border for the main pattern region R1 of the EUV reticle 200. The black border region R2 may be designed to be substantially non-reflective with respect to EUV light. In the embodiment illustrated in FIG. 14B, trenches (or recesses) T1 are formed in the absorber layer 240, the capping layer 230, and the multi-layer structure 220, where the location of the trenches T1 corresponds to the black border region R2 of the EUV reticle 200. The mark region R3 is placed outside the main pattern region R1 and used for reticle alignment. For example, the mark region R3 include patterns for Transmission Image Sensor (TIS) reticle alignment. The reticle alignment is performed before exposing a wafer inside the scanner. The outer region R4 surrounds the black border region R2 in a top view and includes a rest of the EUV reticle 200 outside the black border region R2 and the mark region R3. The outer region R4 may not be specifically configured to be non-reflective with respect to EUV light, and thus the outer region R4 may have a greater EUV reflectivity than the black border region R2.

In the present embodiments, the reticle 200 is a EUV NCAR reticle. During the reticle fabrication process, except for the mark region R3, a portion of a resist (e.g., NCAR) out of the black border region R2 is free of exposure. Due to the property of NCAR, except for the mark region R3, no resist exists out of the black border region R2. As a result, except for the mark region R3, the region of the reticle 200 outside the black border region R2 is free of the absorber layer 240.

As the reticle 200 is oriented face-down within the inner pod, the contact patterns SP22 of the contact region SP2 of the inner baseplate 120 (referring to FIGS. 1A and 1B) are in contact with a front surface 200F of the reticle 200, which is a front surface of the capping layer 230 in the EUV NCAR reticle. In some cases where the contact pattern includes a single pin, the single pin may be damaged by the EUV reticle and leaving carbon defect on the front surface of the EUV reticle, which in turn may result in imprint or scratch. In the cases where the contact pattern include the multiple separated pins, the front surface of the EUV reticle (e.g., the front surface of the capping layer) may be damaged by the pins since the multiple separated pins have a small area for contacting the reticle, which in turn will induce the Ru defects (from the capping layer) on the front surface of the EUV reticle due to high pressure between the pins and the reticle.

In some embodiments of the present disclosure, the contact pattern SP22 is designed to include parallel strips. Through the configuration, the contact pattern SP22 have a suitable contact area avoiding a high pressure between the auxiliary structure and the reticle 200, thereby avoiding the Ru defects on the front surface 200F of the EUV reticle 200. Also, the contact pattern SP22 having the parallel strips may have a higher anti-wear rate, and therefore the contact pattern SP22 may not be substantially damaged by the EUV reticle.

FIG. 14C is a cross-sectional view of a reticle 200 fabricated using a positive chemically-amplified resist (PCAR) taken along line M-M of FIG. 14A. The present embodiments are similar to those illustrated in FIG. 14B, except that the reticle 200 is a EUV PCAR reticle. During the reticle fabrication process, except for the mark region R3, a portion of a resist (e.g., PCAR) out of the black border region R2 is free of exposure. Due to the property of PCAR, resist exists out of the black border region R2. As a result, except for the mark region R3, the region of the reticle 200 outside the black border region R2 include the absorber layer 240.

As the reticle 200 is oriented face-down within the inner pod, the contact patterns SP22 of the contact region SP2 of the inner baseplate 120 (referring to FIGS. 1A and 1B) are in contact with a front surface 200F of the reticle 200, which is a front surface of the absorber layer 240 in the EUV PCAR reticle. In some cases where the contact pattern includes a single pin, the single pin may be damaged by the EUV reticle and leaving carbon defect on the front surface of the EUV reticle, which in turn may result in imprint or scratch.

In some embodiments of the present disclosure, the contact pattern SP22 is designed to include parallel strips. The contact pattern SP22 having the parallel strips may have a higher anti-wear rate, and therefore the contact pattern SP22 may not be substantially damaged by the EUV reticle.

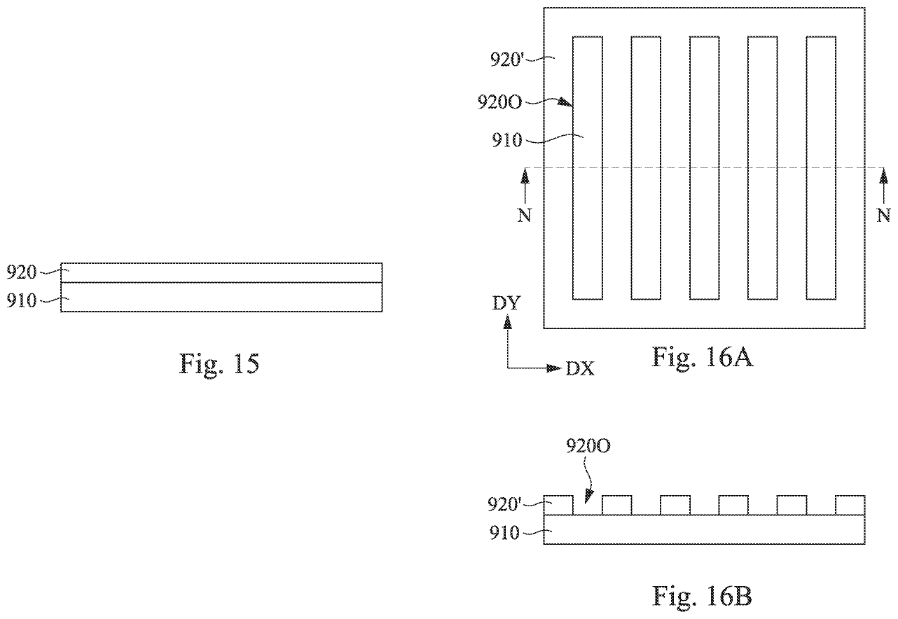

FIGS. 15-20B illustrate a method of manufacturing a contact region of an auxiliary structure at various stages in accordance with some embodiments of the present disclosure. FIGS. 16B, 17B, 18B, 19B, and 20B are cross-sectional views of the semiconductor device (e.g., taken along line N-N in FIGS. 16A, 17A, 18A, 19A, and 20A) at various manufacturing stages in accordance with some embodiments. It is understood that additional steps may be provided before, during, and after the steps shown in FIGS. 15-20B, and some of the steps described below can be replaced or eliminated for additional embodiments of the method. The order of the operations/processes may be interchangeable.

Reference is made to FIG. 15. A photoresist layer 920 is coated on a substrate 910, for example, by spin coating process. The photoresist layer 920 may include suitable photosensitive material. After the photoresist coating, a soft baking process may be performed to evaporate solvent from the photoresist layer 920, thereby making the photoresist layer 920 more solid.

In some embodiments, the substrate 910 may correspond to the aforementioned baseplate SP1 and the raised structure SP21 of the auxiliary structure SP mounted on the main plate MB (referring to FIGS. 1B and 2A). For example, the substrate 910 may include suitable dielectric materials, such as standard thermoplastic, engineering thermoplastic, high-performance thermoplastic, fiber-reinforced high-performance thermoplastic, HMWPE, the like, or the combination thereof.

Reference is made to FIGS. 16A and 16B. A photolithography process is performed such that the photoresist layer 920 includes plural openings 920O exposing the substrate 910. The photolithography process may include processing steps of mask aligning, exposing, post-exposure baking, developing photoresist and hard baking. The openings 920O may include a shape of straight strips. For example, the elongated openings 920O extend substantially along a direction DX and neighboring each other along a direction DY perpendicular to the direction DX, and a length of the elongated openings 920O measured along a direction DX is less than a length of the of the elongated openings 920O measured along a direction DY. In the present embodiments, the elongated openings 920O has a rectangular shape. In some other embodiments, the elongated openings 920O may include an ellipse shape, a triangle shape, a parallelogram shape, or the like.

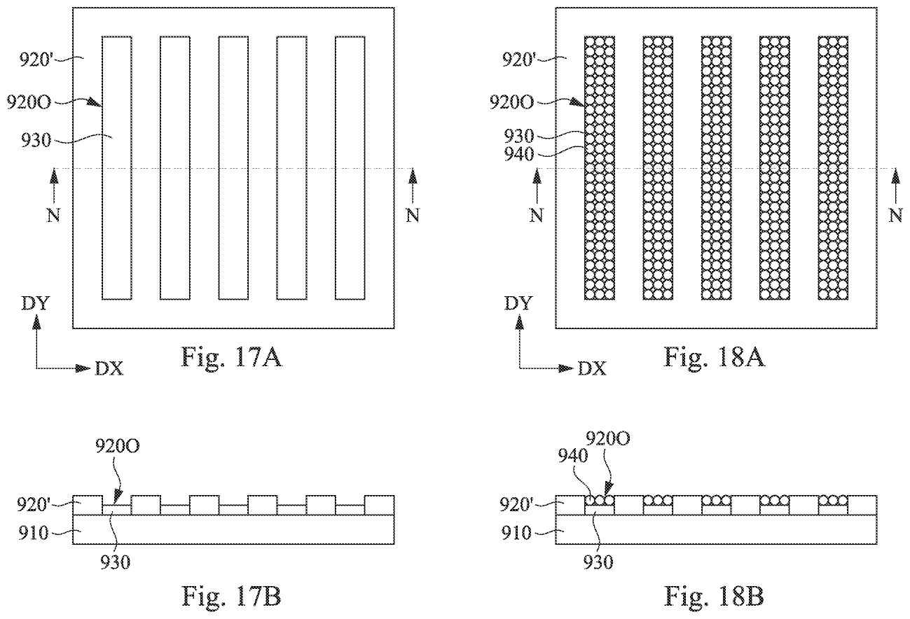

Reference is made to FIGS. 17A and 17B. A metal material 930 is deposited into the elongated openings 920O and over the substrate 910, for example, by an e-beam evaporation process. Following the shapes of the elongated openings 920O, the metal material 930 include an elongated shape (e.g., a rectangular shape) in FIG. 17A. For example, the metal material 930 deposited into the elongated openings 920O forms straight metal strips in the present embodiments. The metal material 930 may be an aluminum layer in some embodiments. The metal material 930 may provide suitable adhesion for the deposition of the subsequent catalyst nanoparticles 940.

Reference is made to FIGS. 18A and 18B. Catalyst nanoparticles 940 are deposited over the metal strips of the metal material 930 by an e-beam evaporation process. In some embodiments, the catalyst nanoparticles 940 may include suitable metal nanoparticles, such as Fe nanoparticles. In some embodiments, a catalyst material (e.g., Fe material) is deposited by the e-beam evaporation process, and the e-beam evaporation process stops once the catalyst material (e.g., Fe material) is nucleated. Thus, the catalyst material is deposited in a form of nanoparticles, rather than a continuous film. The catalyst nanoparticles 940 arranged as the straight parallel strips according to the shape of the metal material 930.

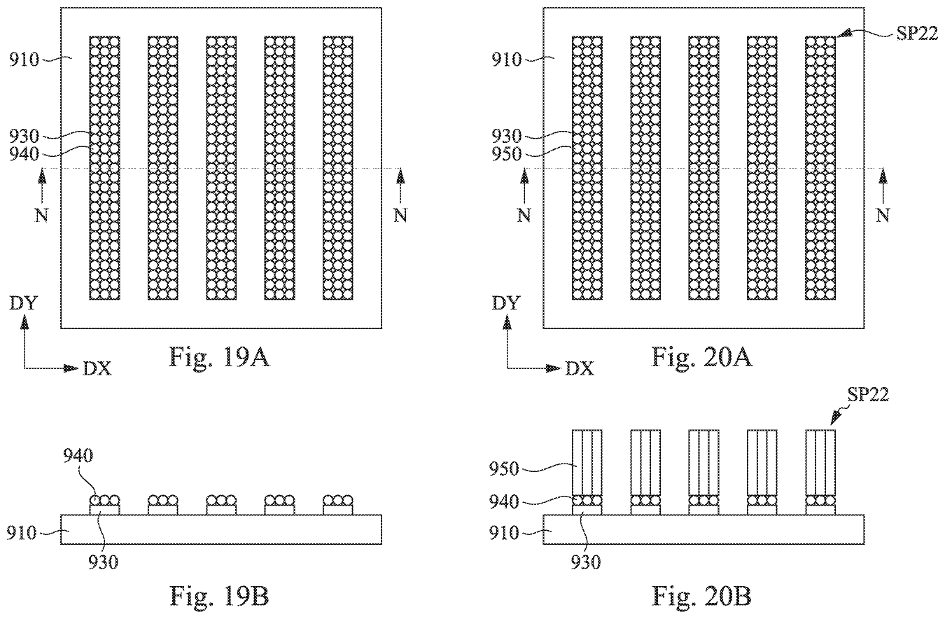

Reference is made to FIGS. 19A and 19B. The photoresist layer 920 (referring to FIGS. 18A and 18B) is removed from the substrate 910 by a suitable stripping-off process. The stripping-off process may also remove residues of the catalyst material and the metal material 930 over the photoresist layer 920 (referring to FIGS. 18A and 18B). After the stripping-off process, the catalyst nanoparticles 940 and the metal material 930 are left on the substrate 910.

Reference is made to FIGS. 20A and 20B. Carbon nanotubes (CNTs) 950 are grown over the catalyst nanoparticles 940 and aligned to the catalyst nanoparticles 940. Few or none CNTs 950 would be grown over the surface of the substrate 910 uncovered by the catalyst nanoparticles 940. In FIG. 20A, the CNTs 950 are arranged as straight parallel strips, which form the contact pattern SP22. Each of the catalyst nanoparticles 940 and the CNTs 950 are depicted as dots in the figures for indicating the alignment therebetween in FIGS. 18A-20B, and the number of the catalyst nanoparticles 940 and the CNTs 950 may vary depending on requirement. It is noted that the figures are not drawn to scale.

In the present embodiments, the CNTs 950 may have a diameter in a range from about 5 nanometers to about 10 nanometers. If the diameter of the CNTs 950 is greater than about 10 nanometers, a friction area of the CNTs 950 may be too large. The CNTs 950 may have a length much greater than the diameter thereof. The length of the CNTs 950 may vary according to process limitation. In some examples, the length of the CNTs 950 may be in a range from about 200 micrometers to about 800 micrometers.

The growth and alignment of the CNTs 950 may include a thermal decomposition of ethylene on the catalyst nanoparticles 940. For example, a gas flow of ethylene is provided to the catalyst nanoparticles 940 at a flow rate in a range from about 50 standard cubic centimeters per minute to about 150 standard cubic centimeters per minute, at a temperature ranging from about 650° C. to about 850° C. If the flow rate of ethylene and/or the temperature are out of the desired range, the growth and alignment of the CNTs 950 may become poor. During the chemical vapor deposition, a buffer gas may be provided at a flow rate ranging from about 1000 standard cubic centimeters per minute to about 1600 standard cubic centimeters per minute, in which the buffer gas may be a Ar/H₂ gas mixture. In some embodiments, a low concentration of water vapor may be carried with a dew point to the reaction furnace by a suitable fraction of Ar/H₂ flow during carbon nanotube growth.

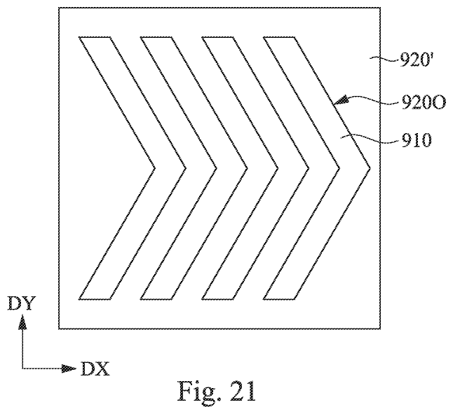

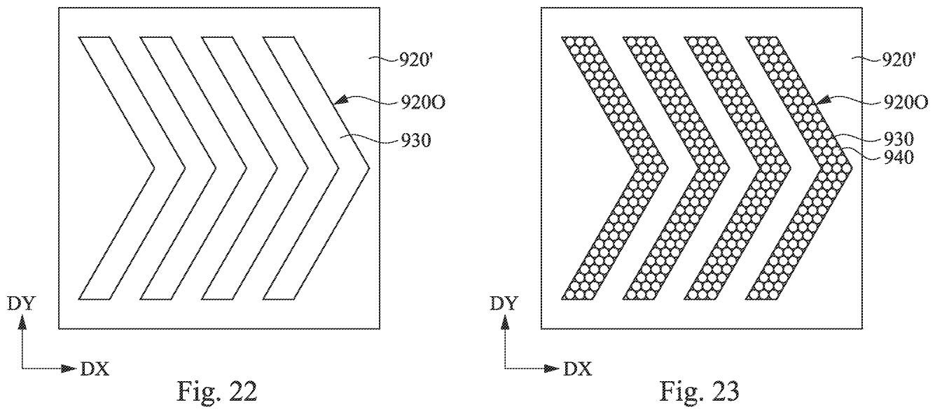

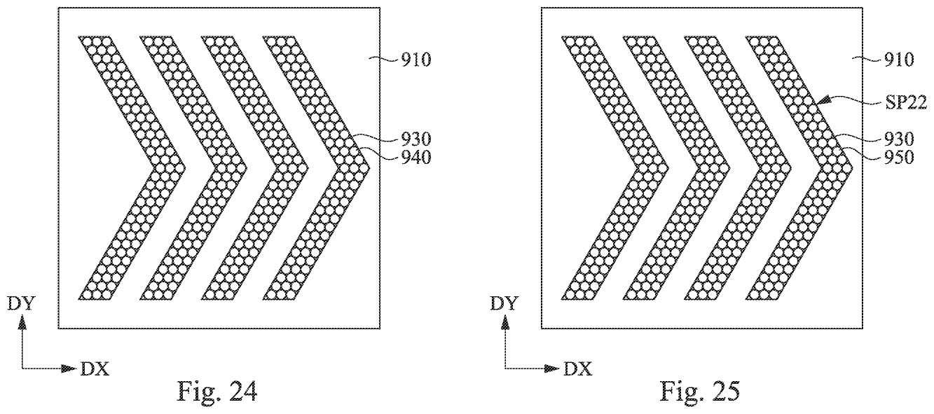

FIGS. 21-25 are top views illustrating a method of manufacturing a contact region of an auxiliary structure at various stages in accordance with some embodiments of the present disclosure. Details of the present embodiments are similar to those illustrated in the embodiments of FIGS. 15-20B, except that the contact pattern SP22 includes plural angle parallel strips in the present embodiments. For example, in FIG. 21, the photolithography process is performed such that the openings 920O in the photoresist layer 920 has a shape of angle strip. In FIG. 22, the metal material 930 deposited into the openings 920O forms angle metal strips according to the profile of the openings 920O. In FIG. 23, catalyst nanoparticles 940 are deposited over the metal material 930 and arranged as the angle parallel strips according to the shape of the metal material 930. In FIG. 24, the photoresist layer 920 is stripped off. In FIG. 25, CNTs 950 are grown over the catalyst nanoparticles 940 and aligned to the catalyst nanoparticles 940. As a result, the CNTs 950 are arranged as the angle parallel strips, which form the contact pattern SP22. As aforementioned, this contact pattern SP22 including the angle parallel strips can share more force from different directions. Each of the catalyst nanoparticles 940 and the CNTs 950 are depicted as dots in the figures for indicating the alignment therebetween in FIGS. 23-25, and the number of the catalyst nanoparticles 940 and the CNTs 950 may vary depending on requirement. It is noted that the figures are not drawn to scale. Other details of the present embodiments are similar to those illustrated in the embodiments of FIGS. 15-20B, and thereto not repeated herein.

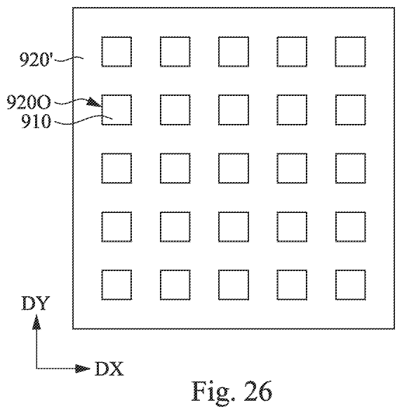

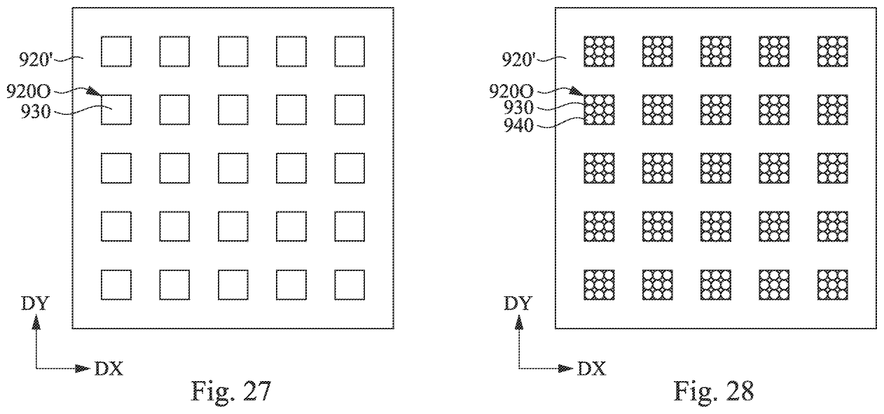

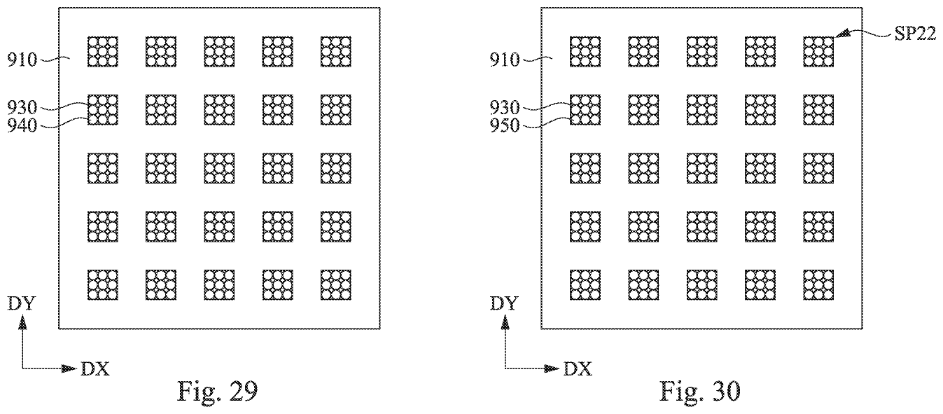

FIGS. 26-30 are top views illustrating a method of manufacturing a contact region of an auxiliary structure at various stages in accordance with some embodiments of the present disclosure. Details of the present embodiments are similar to those illustrated in the embodiments of FIGS. 15-20B, except that the contact pattern SP22 includes plural separated pins in the present embodiments. For example, in FIG. 26, the photolithography process is performed such that the openings 920O in the photoresist layer 920 are islands separated from each other in both directions DX and DY. For example, the openings 920O has a square shape. In FIG. 27, the metal material 930 deposited into the openings 920O forms metal islands separated from each other in both directions DX and DY. For example, the metal islands of the metal material 930 include the square shape according to the profile of the openings 920O. In FIG. 28, catalyst nanoparticles 940 are deposited over the metal material 930 and arranged as the plural squares according to the shape of the metal material 930. In FIG. 29, the photoresist layer 920 is stripped off. In FIG. 30, CNTs 950 are grown over the catalyst nanoparticles 940 and aligned to the catalyst nanoparticles 940. As a result, the CNTs 950 are arranged as plural separated square islands, which form the contact pattern SP22. Each of the catalyst nanoparticles 940 and the CNTs 950 are depicted as dots in the figures for indicating the alignment therebetween in FIGS. 28-30, and the number of the catalyst nanoparticles 940 and the CNTs 950 may vary depending on requirement. It is noted that the figures are not drawn to scale. Other details of the present embodiments are similar to those illustrated in the embodiments of FIGS. 15-20B, and thereto not repeated herein.

Based on the above discussions, it can be seen that the present disclosure offers advantages over semiconductor processes. It is understood, however, that other embodiments may offer additional advantages, and not all advantages are necessarily disclosed herein, and that no particular advantage is required for all embodiments. One advantage is that an auxiliary structure in inner pod of EUV dual pod is designed with a strip-type contact pattern to avoid the film scratch due to the friction between the EUV reticle and the auxiliary structure. Another advantage is that the auxiliary structure may include one or more suitable flexible materials, thereby avoiding two hard material of inner pod friction during pod transferring.

According to some embodiments of the present disclosure, a reticle carrier includes an inner pod, a first auxiliary structure, and an outer pod. The inner pod is configured to receive a reticle. The inner pod comprises an inner baseplate and an inner cover plate, and an inner surface of the inner baseplate and an inner surface of the inner cover plate face each other. The first auxiliary structure is on one of the inner surface of the inner baseplate and the inner surface of the inner cover plate. The first auxiliary structure includes a raised structure and a contact pattern on the raised structure, and the contact pattern includes a plurality of parallel strips. The outer pod houses the inner pod.

According to some embodiments of the present disclosure, a reticle carrier includes an inner pod, an auxiliary structure, and an outer pod. The inner pod is configured to receive a reticle. The inner pod comprises an inner baseplate and an inner cover plate, and an inner surface of the inner baseplate and an inner surface of the inner cover plate face each other. The auxiliary structure is on one of the inner surface of the inner baseplate and the inner surface of the inner cover plate. The auxiliary structure comprises a substrate and a plurality of carbon nanotubes (CNTs) extending upward over the substrate. The outer pod houses the inner pod.

According to some embodiments of the present disclosure, a method for manufacturing an auxiliary structure in a reticle carrier is provided. The method includes forming a photoresist layer over a substrate, wherein the photoresist layer has a plurality of openings; depositing a metal material into the openings in the photoresist layer; depositing a plurality of metal catalyst nanoparticles over the metal material; and growing a plurality of carbon nanotubes (CNTs) from the metal catalyst nanoparticles.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A reticle carrier, comprising:
an inner pod configured to receive a reticle, wherein the inner pod comprises an inner baseplate and an inner cover plate, and an inner surface of the inner baseplate and an inner surface of the inner cover plate face each other;
a first auxiliary structure on one of the inner surface of the inner baseplate and the inner surface of the inner cover plate, wherein the first auxiliary structure comprises a raised structure and a contact pattern on the raised structure, and the contact pattern comprises a plurality of parallel strips; and
an outer pod housing the inner pod.

2. The reticle carrier of claim 1, wherein each of the parallel strips has a substantially flat surface facing away from the raised structure.

3. The reticle carrier of claim 1, wherein the first auxiliary structure further comprises a contact layer over the parallel strips of the contact pattern, and the contact layer is made of a flexible material.

4. The reticle carrier of claim 1, wherein the parallel strips of the contact pattern are straight parallel strips extending along a first side of the raised structure to a second side of the raised structure along a same direction.

5. The reticle carrier of claim 1, wherein the parallel strips of the contact pattern are angle parallel strips, and each of the angle parallel strips has a first portion extending along a first direction and a second portion extending along a second direction different from the first direction.

6. The reticle carrier of claim 1, wherein the parallel strips of the contact pattern are curved parallel strips.

7. The reticle carrier of claim 1, wherein the contact pattern comprises a material different from the raised structure.

8. The reticle carrier of claim 1, wherein a stiffness of the contact pattern is less than a stiffness of the raised structure.

9. The reticle carrier of claim 1, wherein the contact pattern comprises a plurality of carbon nanotubes (CNTs) extending upward over the raised structure.

10. The reticle carrier of claim 1, further comprising:
a second auxiliary structure on another one of the inner surface of the inner baseplate and the inner surface of the inner cover plate, wherein a top view of a contact pattern of the second auxiliary structure is different from a top view of the contact pattern of the first auxiliary structure.

11. The reticle carrier of claim 1, further comprising:
a third auxiliary structure on said one of the inner surface of the inner baseplate and the inner surface of the inner cover plate, wherein a top view of a contact pattern of the third auxiliary structure is different from a top view of the contact pattern of the first auxiliary structure.

12. A reticle carrier, comprising:
an inner pod configured to receive a reticle, wherein the inner pod comprises an inner baseplate and an inner cover plate, and an inner surface of the inner baseplate and an inner surface of the inner cover plate face each other;
an auxiliary structure on one of the inner surface of the inner baseplate and the inner surface of the inner cover plate, wherein the auxiliary structure comprises a substrate and a plurality of carbon nanotubes (CNTs) extending upward over the substrate; and
an outer pod housing the inner pod.

13. The reticle carrier of claim 12, wherein the auxiliary structure further comprises a plurality of metal catalyst nanoparticles between the substrate and the carbon nanotubes.

14. The reticle carrier of claim 12, wherein the auxiliary structure further comprises a plurality of metal strips between the substrate and the carbon nanotubes, and the carbon nanotubes form a plurality of strips from a top view.

15. The reticle carrier of claim 12, wherein the substrate has a raised structure supporting the carbon nanotubes.

16. A method for manufacturing an auxiliary structure in a reticle carrier, comprising:
forming a photoresist layer over a substrate, wherein the photoresist layer has a plurality of openings;
depositing a metal material into the openings in the photoresist layer;
depositing a plurality of metal catalyst nanoparticles over the metal material; and
growing a plurality of carbon nanotubes (CNTs) from the metal catalyst nanoparticles.

17. The method of claim 16, wherein depositing the metal material into the openings in the photoresist layer forms a plurality of straight metal strips, and the grown CNTs forms a plurality of straight strips.

18. The method of claim 16, wherein depositing the metal material into the openings in the photoresist layer forms a plurality of angle metal strips, and the grown CNTs forms a plurality of angle strips.

19. The method of claim 16, wherein depositing the metal material into the openings in the photoresist layer forms a plurality of metal islands, and the grown CNTs forms a plurality of islands.

20. The method of claim 16, further comprising:
removing the photoresist layer from the substrate prior to growing the CNTs and after depositing the metal catalyst nanoparticles.
